(19) United States
(12) Patent Application Publication
(10) Pub. No.: US 2014/0284571 A1
(43) Pub. Date: Sep. 25, 2014

(54) ELECTROOPTICAL DEVICE AND ELECTRONIC APPARATUS

(71) Applicant: SEIKO EPSON CORPORATION, Tokyo (JP)

(72) Inventor: Takeshi NOMURA, Shiojiri-shi (JP)

(73) Assignee: SEIKO EPSON CORPORATION, Tokyo (JP)

(21) Appl. No.: 14/196,849

(22) Filed: Mar. 4, 2014

(30) Foreign Application Priority Data
Mar. 25, 2013 (JP) 2013-061550

(51) Int. Cl. H01L 27/02; H01L 27/32

(52) U.S. Cl. CPC H01L 27/0248; H01L 27/3241
USPC 257/40

(57) ABSTRACT

Provided is an electrooptical device, an electronic apparatus, and the like that can efficiently discharge static electricity compared to related art. An electrooptical device (100) includes a pad (300), a plurality of organic light-emitting diodes (215), a VCT electrode (250) that is electrically and mutually connected to cathodes of the organic light-emitting diodes (215), and a protection element (312) that is electrically connected to the pad (300) at one end and to the VCT electrode (250) at the other end. The pad (300) may be arranged along each of at least three sides out of outer peripheral sides of a substrate on which the electrooptical device (100) is formed, or may be arranged as one of a plurality of pads arranged along the outer peripheral sides of the substrate.

### CROSS-REFERENCE TO RELATED APPLICATIONS

This application claims priority to Japanese Patent Application No. 2013-061550 filed on Mar. 25, 2013.

The entire disclosure of Japanese Patent Application No. 2013-061550 is hereby incorporated herein by reference.

### BACKGROUND

1. Technical Field

The present invention relates to an electrooptical device, an electronic apparatus, and the like. For example, the invention relates to an electrooptical device that uses organic light-emitting diodes as electrooptical elements, an electronic apparatus that includes such an electrooptical device, and the like.

2. Related Art

In recent years, various techniques have been proposed in relation to an electrooptical device that uses light-emitting elements such as organic light-emitting diodes (hereinafter referred to as OLEDs) as electrooptical elements. In an electrooptical device of this sort, a plurality of scan lines and a plurality of data lines are arranged in such a manner that the former intersects the latter, and a plurality of pixel circuits are arranged in a matrix in correspondence with the intersections between the scan lines and the data lines. Each pixel circuit includes at least a drive transistor and a light-emitting element. When a data signal corresponding to a tone level of the pixel is supplied to a gate of the drive transistor, the drive transistor supplies current corresponding to its gate-to-source voltage to the light-emitting element. The light-emitting element emits light of luminance corresponding to the current from the drive transistor.

Such an electrooptical device is suitably applied to a microdisplay such as an electronic viewfinder (hereinafter referred to as EVF) and a head-mounted display (hereinafter referred to as HMD). In this case, the electrooptical device is expected to include an increased number of pixels with the size of each pixel kept to the minimum, and to display higher-quality images on a screen of a limited size. Therefore, the size of a semiconductor substrate (chip) on which an electrooptical device is formed tends to increase.

On the other hand, it is important for an electrooptical device of this sort to take measures against damage by electrostatic discharge (hereinafter referred to as ESD) so as to prevent impairment, occurrence of malfunction, and the like caused by ESD. In view of this, various techniques have been proposed in relation to measures taken by an electrooptical device against ESD damage. For example, JP-A-2008-211223, which is an example of related art, discloses an electrooptical device including a semiconductor device in which a protection circuit for protecting a semiconductor circuit from ESD is arranged between the semiconductor circuit and an input terminal for supplying a signal to the semiconductor circuit.

As disclosed in JP-A-2008-211223, for example, a protection circuit for protecting a semiconductor circuit and the like from ESD is configured to discharge static electricity that has entered from a terminal to a power supply line in the semiconductor circuit and the like to which a high-potential side power supply voltage is supplied, or to a power supply line in the semiconductor circuit to which a ground voltage is supplied.

However, according to this technique, for some terminals (pads) arranged along outer peripheral sides of a semiconductor substrate on which the electrooptical device is formed, an increase in the size of the substrate increases a distance to a terminal to which the high-potential power supply voltage or the ground voltage is supplied.

FIG. 16 is a diagram for describing measures taken by a general electrooptical device against ESD damage. Specifically, FIG. 16 is a plan view schematically showing the arrangement of terminals of an electrooptical device.

An electrooptical device 10 is formed on a semiconductor substrate. A display unit 12 and a plurality of pads 14 are provided on the semiconductor substrate. In the display unit 12, a plurality of pixel circuits are arranged in a matrix. The plurality of pads 14 are arranged along outer peripheral sides of the substrate. A control signal and a power supply voltage are supplied from the outside to the pixel circuits constituting the display unit 12 via any of the plurality of pads 14.

Note that in the case where the electrooptical device 10 includes a drive circuit that supplies a drive signal to the pixel circuits constituting the display unit 12, the drive circuit is arranged between the display unit 12 and the plurality of pads 14, and various types of signals for controlling the drive circuit and a power supply voltage are supplied from the outside to the plurality of pads 14.

Among the plurality of pads 14, a pad 14a is farthest from a pad 14b that is arranged at a position opposing the pad 14a via the display unit 12. For example, provided that the pad 14b is a power supply pad to which a high-potential side power supply voltage or a ground voltage is supplied from the outside, a static electricity protection circuit 16a, which is arranged in the vicinity of the pad 14a, is connected to the pad 14b via a long interconnect 18. This increases the impedance of the interconnect 18, which leads to a concern that static electricity that has entered from the pad 14a may not be efficiently discharged to the power supply pad 14b. While it is conceivable that the interconnect 18 be arranged above or below the display unit 12 in a thickness direction, the impedance of the interconnect 18 increases in either case, thus leading to a similar concern.

### SUMMARY

An advantage of some aspects of the invention is that it is possible to provide an electrooptical device, an electronic apparatus, and the like that can efficiently discharge static electricity compared to related art.

(1) In a first aspect of the invention, an electrooptical device includes a pad, a plurality of organic light-emitting diodes, a first electrode, and a first protection element. The first electrode is electrically and mutually connected to cathodes of the plurality of organic light-emitting diodes. The first protection element is electrically connected to the pad at one end and to the first electrode at the other end.

In the first aspect, the electrooptical device includes the plurality of organic light-emitting diodes as well as the first protection element that is connected between the pad and the first electrode mutually connected to the cathodes of the organic light-emitting diodes. In this way, even if the size of the electrooptical device (or the size of a substrate on which the electrooptical device is formed) increases, static electricity can be discharged to the lower-impedance first electrode in the state where the first protection element and the first electrode are connected by a connection interconnect that is shorter than a connection interconnect used in related art. As a result, the first aspect makes it possible to provide the electrooptical device that can efficiently discharge static electricity compared to related art.

(2) In a second aspect of the invention, the first protection element in the electrooptical device according to the first aspect is one of a protection diode, an off transistor, and a thyristor.

In the second aspect, one of the protection diode, the off transistor, and the thyristor is used as the first protection element. In this way, static electricity can be efficiently discharged compared to related art simply by changing the electrode connected to the first protection element.

(3) In a third aspect of the invention, the electrooptical device according to the first or second aspect further includes a plurality of drive transistors, a second electrode, and a second protection element. The plurality of drive transistors supply current to the plurality of organic light-emitting diodes. The second electrode is electrically and mutually connected to sources of the plurality of drive transistors. The second protection element is electrically connected to the pad at one end and to the second electrode at the other end.

In the third aspect, the electrooptical device further includes the second protection element that is connected between the pad and the second electrode mutually connected to sources of the drive transistors that supply current to the organic light-emitting diodes. In this way, even if the size of the electrooptical device (or the size of the substrate on which the electrooptical device is formed) increases, static electricity can be discharged to the lower-impedance second electrode via the second protection element. As a result, the third aspect makes it possible to provide the electrooptical device that can efficiently discharge static electricity compared to related art.

(4) In a fourth aspect of the invention, the second protection element in the electrooptical device according to the third aspect is a protection diode or an off transistor.

In the fourth aspect, the protection diode or the off transistor is used as the second protection element. In this way, static electricity can be efficiently discharged compared to related art simply by changing the electrode connected to the second protection element.

(5) In a fifth aspect of the invention, in the electrooptical device according to the third or fourth aspect, the second electrode is arranged so as to be superimposed with a display area in which the plurality of organic light-emitting diodes are formed in a plan view, and the first electrode is constituted by one or more electrodes that are arranged so as to surround the second electrode.

In the fifth aspect, the display area is effectively used in the arrangement. Therefore, the impedances of the first electrode and the second electrode can be further lowered, and static electricity that has entered from the pad can be discharged in a more efficient manner.

(6) In a sixth aspect of the invention, in the electrooptical device according to the third or fourth aspect, the second electrode is arranged so as to be superimposed with a display area in which the plurality of organic light-emitting diodes are formed in a plan view, and the first electrode has outer peripheral sides extending along two mutually-intersecting sides out of outer peripheral sides of the second electrode.

In the case where the second electrode has a rectangular shape, the first electrode may have outer peripheral sides extending along three sides out of the outer peripheral sides of the second electrode. In the sixth aspect, the display area is effectively used in the arrangement. Therefore, the impedances of the first electrode and the second electrode can be further lowered, and static electricity that has entered from the pad can be discharged in a more efficient manner.

(7) In a seventh aspect of the invention, the electrooptical device according to any one of the third to sixth aspects further includes a connection interconnect that electrically connects the second electrode and the other end of the second protection element. The connection interconnect is arranged so as to be superimposed with the first electrode in a plan view.

In the seventh aspect, as the first electrode is arranged on the outer side of the second electrode, the distance of connection between the first electrode and the first protection element can be minimized. In addition, the connection interconnect connecting the second electrode, which is arranged on the inner side of the first electrode, and the second protection element is arranged so as to be superimposed with the first electrode in a plan view. In this way, the distance of connection between the second electrode and the second protection element can be minimized, and therefore static electricity can be discharged in a more efficient manner.

(8) In an eighth aspect of the invention, the electrooptical device according to any one of the first to seventh aspects further includes a power supply pad to which a ground voltage is supplied. A synthetic impedance combining an impedance of an interconnect connecting the first electrode and the first protection element and an impedance of the first electrode is lower than an impedance of an interconnect electrically connected to the power supply pad.

In the eighth aspect, the synthetic impedance combining the impedance of the interconnect connecting the first electrode and the first protection element and the impedance of the first electrode is lower than the impedance of the interconnect connected to the power supply pad to which the power supply voltage is supplied. This makes it possible to provide the electrooptical device that can efficiently discharge static electricity compared to related art.

(9) In a ninth aspect of the invention, in the electrooptical device according to any one of the first to eighth aspects, the pad is one of a plurality of pads that are arranged along outer peripheral sides of the substrate on which the electrooptical device is formed.

In the case where the plurality of pads are arranged along the outer peripheral sides of the substrate, even if the size of the substrate increases, the ninth aspect makes it possible to provide the electrooptical device that can efficiently discharge static electricity compared to related art.

(10) In a tenth aspect of the invention, in the electrooptical device according to any one of the first to eighth aspects, the pads are arranged along each of at least three sides out of the outer peripheral sides of the substrate on which the electrooptical device is formed.

In the case where the plurality of pads are arranged along each of at least three sides out of the outer peripheral sides of the substrate, even if the size of the substrate increases, the tenth aspect makes it possible to provide the electrooptical device that can efficiently discharge static electricity compared to related art.

(11) In an eleventh aspect of the invention, in the electrooptical device according to any one of the first to tenth aspects, the pad is a mount pad for the electrooptical device.

The eleventh aspect makes it possible to provide the electrooptical device that can efficiently discharge static electricity entering from the mount pad, which is used in mounting the electrooptical device in a display module and the like, compared to related art.

(12) In a twelfth aspect of the invention, an electronic apparatus includes the electrooptical device according to any one of the first to eleventh aspects.

The twelfth aspect makes it possible to provide the electronic apparatus to which the electrooptical device is applied that can efficiently discharge static electricity entering from the pad compared to related art.

### BRIEF DESCRIPTION OF THE DRAWINGS

The invention will be described with reference to the accompanying drawings, wherein like numbers reference like elements.

FIG. 1 shows an overview of a configuration of an electrooptical device according to the present embodiment.

FIG. 2 shows one example of a circuit arrangement for the electrooptical device of FIG. 1 in a plan view.

FIG. 3 shows one example of a configuration of a pixel circuit of FIG. 1.

FIG. 4 shows one example of an arrangement of a VEL electrode and a VCT electrode of FIG. 3 in a plan view.

FIG. 5 is a diagram for describing a protection circuit according to the present embodiment.

FIG. 6 is a circuit diagram showing one example of a configuration of the protection circuit of FIG. 5.

FIG. 7 is a diagram for describing connection interconnects connecting the VEL electrode and protection circuits.

FIG. 8 schematically shows one example of a cross-sectional configuration of the electrooptical device taken along line A-A of FIG. 2.

FIG. 9 shows one example of an arrangement of a VEL electrode and a VCT electrode in an electrooptical device according to a first modification example of the present embodiment in a plan view.

FIG. 10 shows one example of an arrangement of a VEL electrode and a VCT electrode in an electrooptical device according to a second modification example of the present embodiment in a plan view.

FIG. 11 shows one example of an arrangement of a VEL electrode and a VCT electrode in an electrooptical device according to a third modification example of the present embodiment in a plan view.

FIG. 12 shows one example of an arrangement of a VEL electrode and a VCT electrode in an electrooptical device according to a fourth modification example of the present embodiment in a plan view.

FIG. 13 shows one example of a configuration of a display module to which the electrooptical device according to the present embodiment is applied.

FIG. 14 shows an external appearance of an HMD serving as an electronic apparatus according to the present embodiment.

FIG. 15 shows an overview of an optical configuration of the HMD shown in FIG. 14.

FIG. 16 is a diagram for describing measures taken by a general electrooptical device against ESD damage.

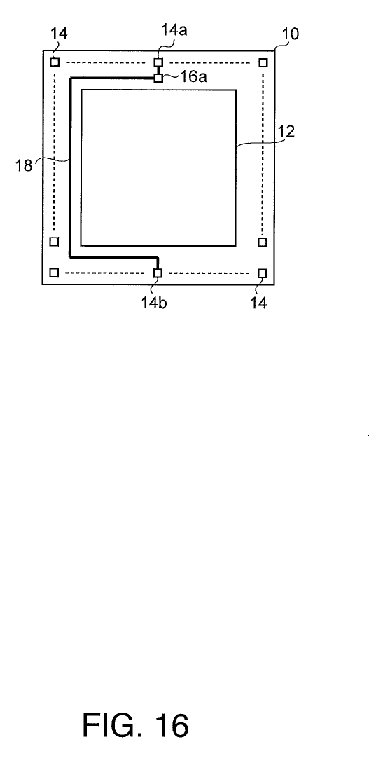

### DESCRIPTION OF EXEMPLARY EMBODIMENTS

The following describes an embodiment of the invention in detail with reference to the drawings. It should be noted that the embodiment described below is not intended to unreasonably limit the contents of the invention described in the attached claims. Furthermore, not all configurations described below are constitutional elements that are indispensable for achieving the advantage of the invention.

Electrooptical Device

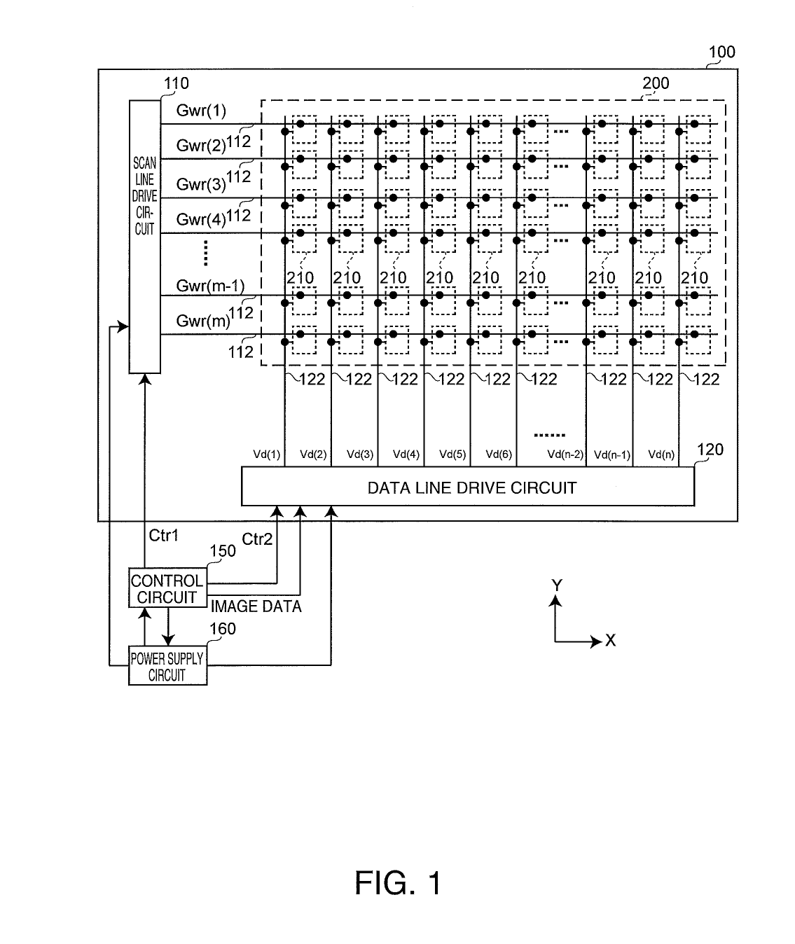

FIG. 1 shows an overview of a configuration of an electrooptical device according to one embodiment of the invention.

An electrooptical device 100 according to the present embodiment is an organic EL device in which a plurality of pixel circuits, drive circuits, and the like are formed on, for example, a silicon substrate. The plurality of pixel circuits use OLEDs as light-emitting elements. The drive circuits supply a drive signal and the like to the pixel circuits.

The electrooptical device 100 includes a scan line drive circuit 110, a data line drive circuit 120, and a display unit 200. A control circuit 150 and a power supply circuit 160 are provided outside the electrooptical device 100.

The electrooptical device 100 may be configured such that at least one of the scan line drive circuit 110 and the data line drive circuit 120 is provided outside the electrooptical device 100. Also, the electrooptical device 100 may be configured such that at least one of the control circuit 150 and the power supply circuit 160 is built therein.

The display unit 200 includes a plurality of pixel circuits 210 arrayed in a matrix. The plurality of pixel circuits 210 are all configured in the same manner. In the display unit 200, m scan lines 112 are arrayed so as to extend in the X direction of FIG. 1 (m is an integer equal to or larger than two). In the display unit 200, data lines 122 are also arrayed in n columns so as to extend in the Y direction of FIG. 1 (n is an integer equal to or larger than two). The pixel circuits 210 are provided in correspondence with the intersections between m rows of scan lines 112 and n columns of data lines 122. Three pixel circuits 210 corresponding to the intersections between one scan line 112 and three data lines 122 adjacent in the X direction respectively correspond to R (red), G (green) and B (blue) pixels, representing one dot of pixels forming a color image.

The control circuit 150 supplies control signals Ctr1, Ctr2 to the scan line drive circuit 110 and the data line drive circuit 120, and supplies image data corresponding to pixels of each row to the data line drive circuit 120. Furthermore, the control circuit 150 can control generation of various types of power supply voltages by the power supply circuit 160.

The control signals Ctr1 include a vertical synchronization signal, a horizontal synchronization signal, a clock signal and an enable signal, which are pulse signals for controlling the scan line drive circuit 110.

The control signals Ctr2 include a horizontal synchronization signal, a dot clock signal DCLK, a latch pulse signal LP and an enable signal for controlling the data line drive circuit 120.

The image data corresponds to per-pixel tone levels of a row selected by a scan signal from the scan line drive circuit 110.

Based on the control signals Ctr1, the scan line drive circuit 110 generates scan signals Gwr(1) to Gwr(m) for scanning the scan lines 112 in order, one row at a time, in frame periods defined by the vertical synchronization signal. In FIG. 1, scan signals supplied to the scan lines 112 in the first, second, third, . . . , (m−1)^{th}, and m^{th} rows are indicated as Gwr(1), Gwr(2), Gwr(3), . . . , Gwr(m−1), and Gwr(m), respectively.

Note that the scan line drive circuit 110 generates control signals to be supplied to the pixel circuits on a per-row basis in addition to the scan signals Gwr(1) to GWr(m). These control signals, however, are omitted from FIG. 1.

The data line drive circuit 120 supplies data signals Vd(1) to Vd(n) to the corresponding data lines 122 in each horizontal scan period. The data signals Vd(1) to Vd(n) correspond to tone levels of pixels of a row selected by the scan line drive circuit 110.

The power supply circuit 160 generates and supplies various types of power supply voltages necessary for the scan line drive circuit 110, the data line drive circuit 120 and the control circuit 150.

More specifically, the power supply circuit 160 supplies, to the scan line drive circuit 110, a power supply voltage for causing the scan line drive circuit 110 to operate, and various types of power supply voltages for generating the scan signals Gwr(1) to Gwr(m) and control signals to be supplied to the pixel circuits.

The power supply circuit 160 also supplies, to the data line drive circuit 120, a power supply voltage for causing the data line drive circuit 120 to operate, and a plurality of tone voltages corresponding to tone levels.

The power supply circuit 160 further supplies, to the pixel circuits constituting the display unit 200, a power supply voltage for causing the pixel circuits to operate.

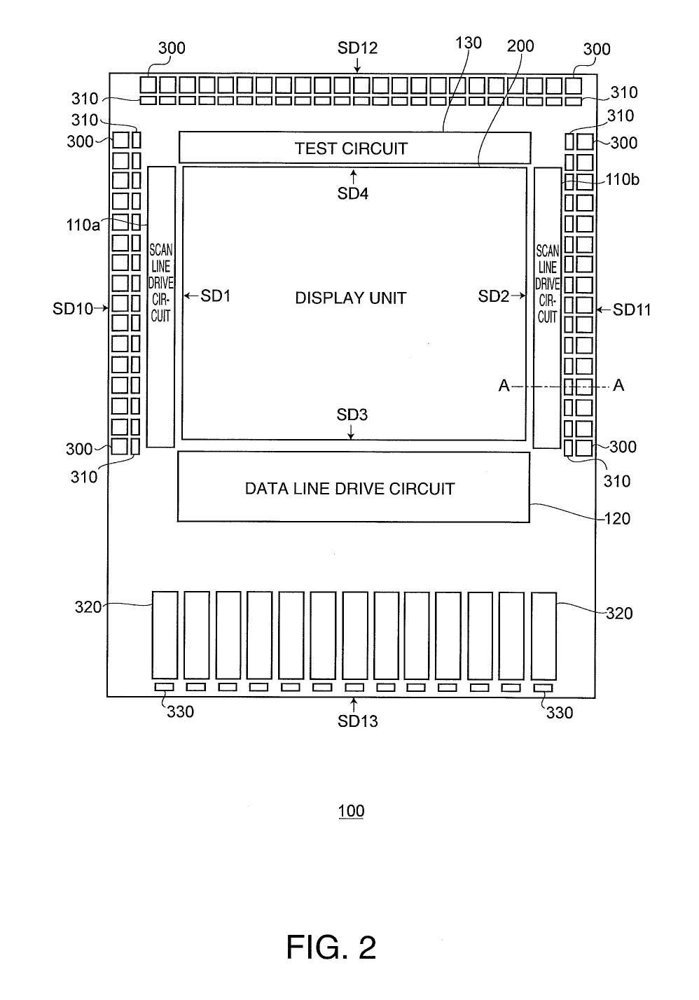

FIG. 2 shows one example of a circuit arrangement for the electrooptical device 100 of FIG. 1 in a plan view. Components of FIG. 2 that are similar to those of FIG. 1 are given the same reference signs thereas, and a description thereof will be omitted as appropriate.

On a semiconductor substrate on which the electrooptical device 100 is formed (hereinafter simply referred to as substrate as appropriate), scan line drive circuits 110a and 110b, the data line drive circuit 120, and a test circuit 130 are arranged along outer peripheral sides of the display unit 200 that has a rectangular shape. Note that the test circuit 130 is not shown in FIG. 1.

The scan line drive circuits 110a and 110b are arranged respectively along two opposing sides SD1 and SD2 out of the outer peripheral sides of the display unit 200. The data line drive circuit 120 is arranged along a side SD3 intersecting the sides SD1 and SD2 out of the outer peripheral sides of the display unit 200. The test circuit 130 is arranged along a side SD4 opposing the side SD3 out of the outer peripheral sides of the display unit 200.

A plurality of pads 300 are arranged as test pads along sides SD10, SD11 and SD12 out of outer peripheral sides of the substrate on which the electrooptical device 100 is formed. The sides SD10 and SD11 oppose each other, and the side SD12 intersects the sides SD10 and SD11. Protection circuits 310 are provided in one-to-one correspondence with the pads 300. Each protection circuit 310 is located in the vicinity of the corresponding pad 300 so as to be closer to an inner side of the substrate than the corresponding pad 300 is.

Furthermore, a plurality of mount pads 320 are arranged along a side SD13 opposing the side SD12 out of the outer peripheral sides of the substrate on which the electrooptical device 100 is formed. Protection circuits 330 are provided in one-to-one correspondence with the mount pads 320. Each protection circuit 330 is located in the vicinity of the corresponding mount pad 320 so as to be closer to an outer side of the substrate than the corresponding mount pad 320 is. Note that the protection circuits 330 are configured in a manner similar to the protection circuits 310.

The scan line drive circuits 110a and 110b both have the function of the scan line drive circuit 110 of FIG. 1, and supply a scan signal and a control signal to the pixel circuits on the same scan line at the same timing. This reduces unevenness in display caused by rounding in a scan signal and the like associated with the positions of the pixel circuits 210 constituting the display unit 200.

The test circuit 130 performs control to verify the operations of the plurality of pixel circuits 210 constituting the display unit 200. More specifically, during a test mode operation, the test circuit 130 performs control to output a data signal for each data line 122, or for each group of data lines 122, via the corresponding pad(s) 300. This enables verification of the plurality of pixel circuits 210 constituting the display unit 200, the data lines 122 connected thereto, and the like.

In the electrooptical device 100 configured in the above-described manner, the protection circuits 310 provided in correspondence with the pads 300 are configured to discharge static electricity to at least one of a VEL electrode and a VCT electrode that are mutually connected to the plurality of pixel circuits 210 constituting the display unit 200.

In order to describe the VEL electrode and the VCT electrode according to the present embodiment, the pixel circuits 210 connected to the VEL electrode and the VCT electrode will now be discussed.

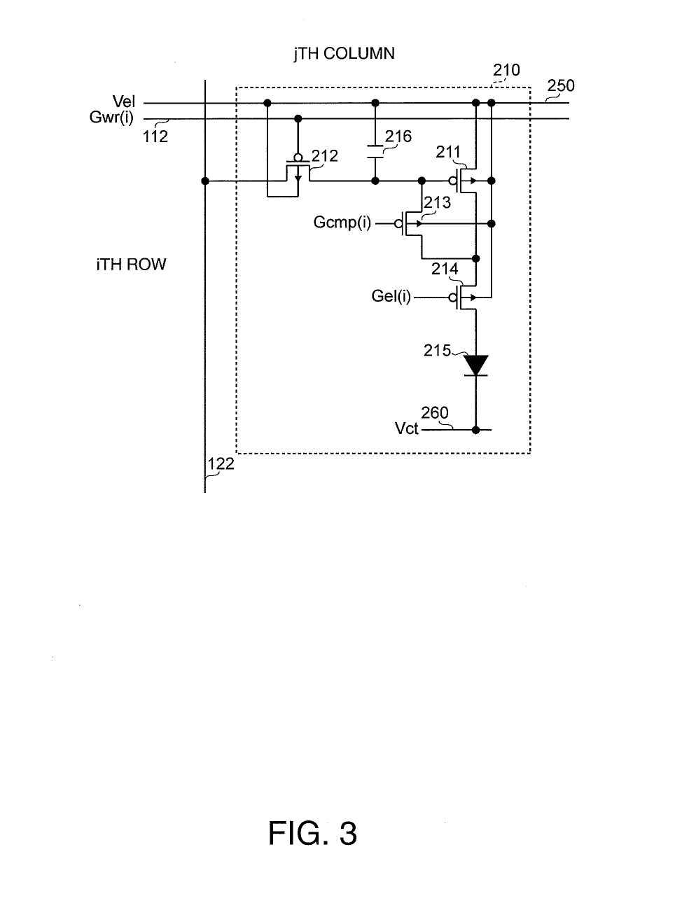

FIG. 3 shows one example of a configuration of the pixel circuits 210 of FIG. 1. Specifically, FIG. 3 shows a pixel circuit in the j^{th} column of the i^{th} row (j and i are both natural numbers). Components of FIG. 3 that are similar to those of FIG. 1 are given the same reference signs thereas, and a description thereof will be omitted as appropriate.

The pixel circuit 210 includes p-type metal-oxide semiconductor (hereinafter referred to as MOS) transistors 211 to 214, an OLED 215, and a holding capacitor 216. A scan signal Gwr(i) and control signals Gcmp(i) and Gel(i), which serve as gate signals for the transistors 212 to 214, are supplied to the pixel circuit 210. The scan signal Gwr(i) and the control signals Gcmp(i) and Gel(i) are supplied from the scan line drive circuit 110 (110a and 110b) in correspondence with the i^{th} row. They are mutually supplied to pixel circuits in columns other than the j^{th} column of the i^{th} row.

The transistor 211 serves as a drive transistor. A source of the transistor 211 is electrically connected to a VEL electrode 250 (second electrode). A drain of the transistor 211 is electrically connected to a drain of the transistor 213 and a source of the transistor 214. A gate of the transistor 211 is electrically connected to a drain of the transistor 212, a source of the transistor 213, and one end of the holding capacitor 216. A voltage Vel, which is at a high-potential side of a power supply in the pixel circuit 210, is supplied to the VEL electrode 250. Note that the voltage Vel is supplied from the power supply circuit 160.

The transistor 212 serves as a writing transistor. A source of the transistor 212 is electrically connected to the data line 122. A gate of the transistor 212 is connected to the scan line 112. The gate of the transistor 212 is controlled by the scan signal Gwr(i), which serves as the gate signal.

The control signal Gcmp(i) is supplied to a gate of the transistor 213, which serves as a threshold compensation transistor. The gate of the transistor 213 is controlled by the control signal Gcmp(i), which serves as the gate signal.

The transistor 214 serves as a current supply control transistor. A drain of the transistor 214 is electrically connected to an anode of the OLED 215. The control signal Gel(i) is supplied to a gate of the transistor 214. The gate of the transistor 214 is controlled by the control signal Gel(i), which serves as the gate signal. Provision of the transistor 214 makes it possible to, for example, prevent the situation in which an unintended image is displayed due to current being supplied to the OLED 215 immediately after power is supplied.

Furthermore, as shown in FIG. 3, the voltage Vel is supplied as a substrate potential for the transistors 211 to 214.

The pixel circuit 210 may be additionally provided with a p-type MOS transistor with a drain electrically connected to the anode of the OLED 215 and with a source supplied with a given initial voltage. By applying the initial voltage to the anode of the OLED 215 via this transistor at a predetermined timing, the electric charge accumulated in a parasitic capacitance of the OLED 215 can be initialized, and therefore display deterioration caused by the parasitic capacitance of the OLED 215 can be prevented.

A cathode of the OLED 215 is electrically connected to a VCT electrode 260 (first electrode). A voltage Vct, which is at a low-potential side of the power supply in the pixel circuit 210, is supplied to the cathode of the OLED 215. On the substrate, the OLED 215 is a light-emitting element that is constituted by the anode, the cathode with light transmissive properties, and a white organic EL layer held between the anode and the cathode. A color filter of R, G or B is superimposed with the cathode, which is the emission side. When current flows from the anode to the cathode of the OLED 215, holes injected from the anode and electrons injected from the cathode recombine in the organic EL layer forming an exciton, and white light is emitted. After being transmitted through the cathode, the white light is colored by the color filter and becomes visible to a viewer.

The other end of the holding capacitor 216 is electrically connected to the VEL electrode 250 and holds the gate-to-source voltage of the transistor 211.

The holding capacitor 216 is formed by making use of a parasitic capacitance of the gate of the transistor 211, or a capacitance formed by conductive layers holding an insulating layer therebetween.

To briefly explain the operations of the pixel circuit 210 shown in FIG. 3, during one horizontal scan period selected by a scan signal, a data signal corresponding to a tone level is written via the transistor 212. Subsequently, the transistor 213 is switched on, and the data signal is held in the holding capacitor 216 with a threshold of the transistor 211 compensated. Thereafter, the transistor 214 is switched on, and current corresponding to the gate-to-source voltage of the transistor 211 is supplied to the OLED 215. In this way, the OLED 215 can emit light of luminance corresponding to a tone level with the threshold of the transistor 211 compensated.

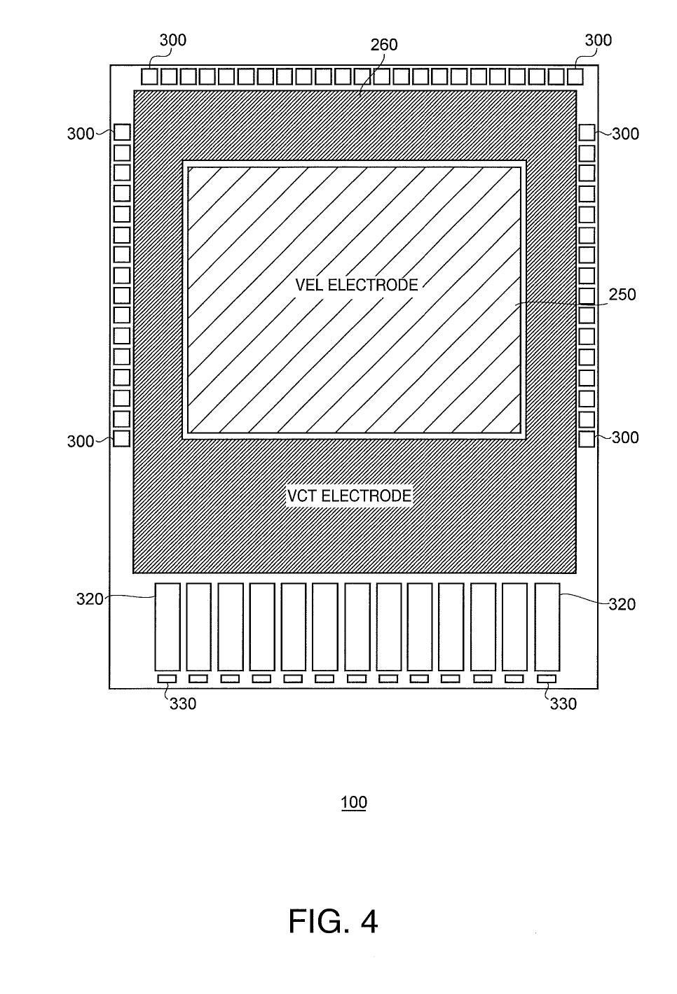

FIG. 4 shows one example of an arrangement of the VEL electrode 250 and the VCT electrode 260 of FIG. 3 in a plan view. Components of FIG. 4 that are similar to those of FIG. 2 or 3 are given the same reference signs thereas, and a description thereof will be omitted as appropriate.

The VEL electrode 250 is arranged so as to be superimposed with the display unit 200, which is a display area in which a plurality of OLEDs are formed, in a plan view. The VEL electrode 250 is electrically connected to any of the plurality of mount pads 320, and the voltage Vel is supplied to the VEL electrode 250 via the connected mount pad 320.

On the other hand, the VCT electrode 260 is arranged so as to surround the VEL electrode 250 in the state where it is electrically disconnected from the VEL electrode 250. The VCT electrode 260 is electrically connected to any of the plurality of mount pads 320, and the voltage Vct is supplied to the VCT electrode 260 via the connected mount pad 320. Thus, each of the plurality of pixel circuits 210 constituting the display unit 200 is connected to the VEL electrode 250 under the same condition. This is intended to reduce unevenness in display.

Note that the voltage Vct can be set at the same potential as a ground voltage Vss. However, in the present embodiment, the plurality of mount pads 320 include a pad for supplying the voltage Vct separately from a power supply pad for supplying the ground voltage Vss. Therefore, synthetic impedance combining the impedance of interconnects connecting the protection circuits 310 (more specifically, protection elements constituting the protection circuits 310) and the VCT electrode 260 and the impedance of the VCT electrode 260 can be lower than the impedance of an interconnect that is electrically connected to the power supply pad for supplying the ground voltage Vss.

Furthermore, the protection circuits 310 (not shown in FIG. 4) located in the vicinity of the pads 300 arranged along the outer peripheral sides of the substrate are electrically connected to the VEL electrode 250 or the VCT electrode 260 via interconnects shorter than those used in related art. Therefore, according to the present embodiment, static electricity can be efficiently discharged to lower-impedance electrodes compared to related art.

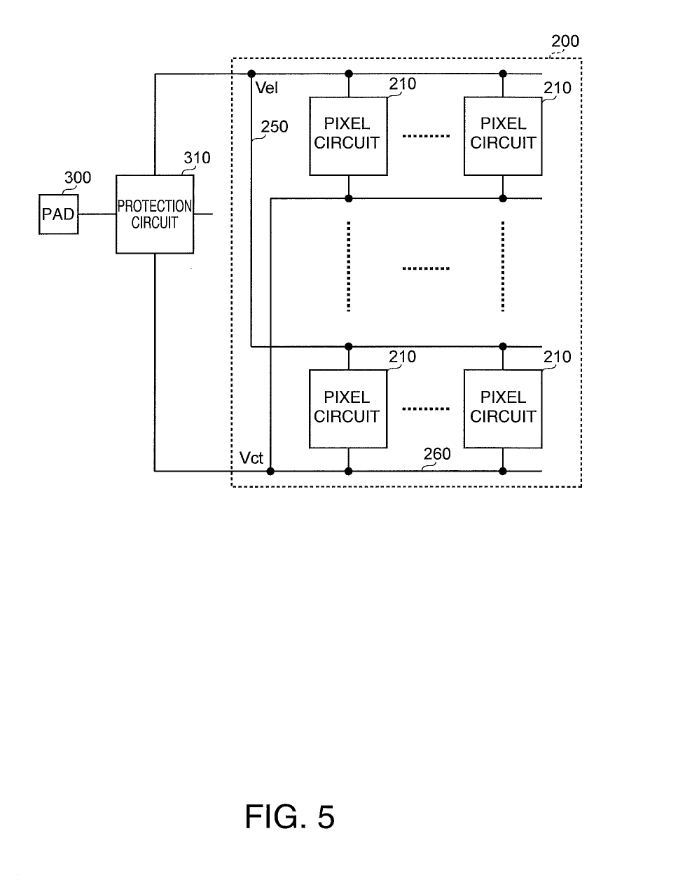

FIG. 5 is a diagram for describing a protection circuit 310 according to the present embodiment. Components of FIG. 5 that are the same as those of FIGS. 1 to 4 are given the same reference signs thereas, and a description thereof will be omitted as appropriate.

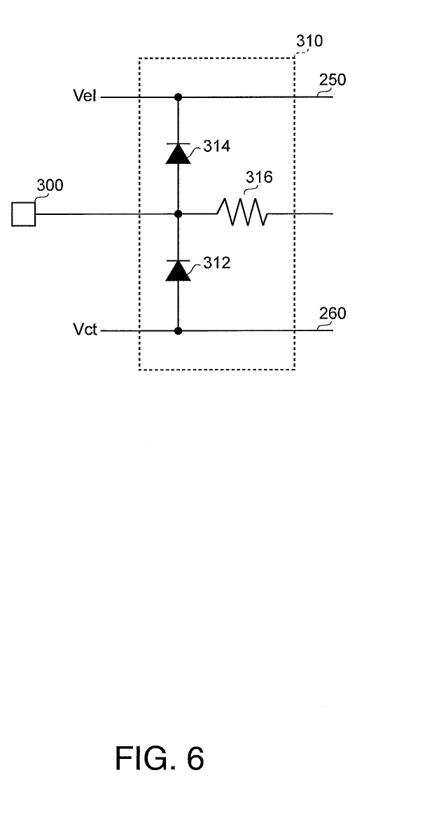

FIG. 6 is a circuit diagram showing one example of a configuration of the protection circuit 310 of FIG. 5. Components of FIG. 6 that are similar to those of FIG. 5 are given the same reference signs thereas, and a description thereof will be omitted as appropriate.

In the present embodiment, the protection circuits 310 of FIG. 2, which are connected to and located in the vicinity of the pads 300, are connected to the VEL electrode 250 and the VCT electrode 260. Static electricity that has entered from the pads 300 is discharged to the VEL electrode 250 or the VCT electrode 260 that has low impedance compared to related art. In this way, internal circuits connected to the protection circuits 310 are protected.

As shown in FIG. 6, the protection circuit 310 includes protection elements 312 and 314 and a protection resistor 316. One end of the protection element 312 (first protection element) is electrically connected to the corresponding pad 300, and the other end thereof is electrically connected to the VCT electrode 260. One end of the protection element 314 (second protection element) is electrically connected to the pad 300, and the other end thereof is electrically connected to the VEL electrode 250.

A That is to say, the electrooptical device 100 can include the pads 300, the plurality of OLEDs 215, the VCT electrode 260 that is electrically and mutually connected to the cathodes of the OLEDs 215, and the protection elements 312 that are each electrically connected to the corresponding pad 300 at one end and electrically connected to the VCT electrode 260 at the other end. In FIG. 6, the protection element 312 is constituted by a protection diode. An anode and a cathode of the protection diode are electrically connected to the VCT electrode 260 and the corresponding pad 300, respectively.

A Alternatively, the protection element 312 may be constituted by an off transistor or a thyristor.

A The electrooptical device 100 can further include the plurality of transistors 211, the VEL electrode 250 that is electrically and mutually connected to the sources of the transistors 211, and the protection elements 314 that are each electrically connected to the corresponding pad 300 at one end and connected to the VEL electrode 250 at the other end. In FIG. 6, the protection element 314 is constituted by a protection diode. An anode and a cathode of the protection diode are electrically connected to the corresponding pad 300 and the VEL electrode 250, respectively.

Alternatively, the protection element 314 may be constituted by an off transistor.

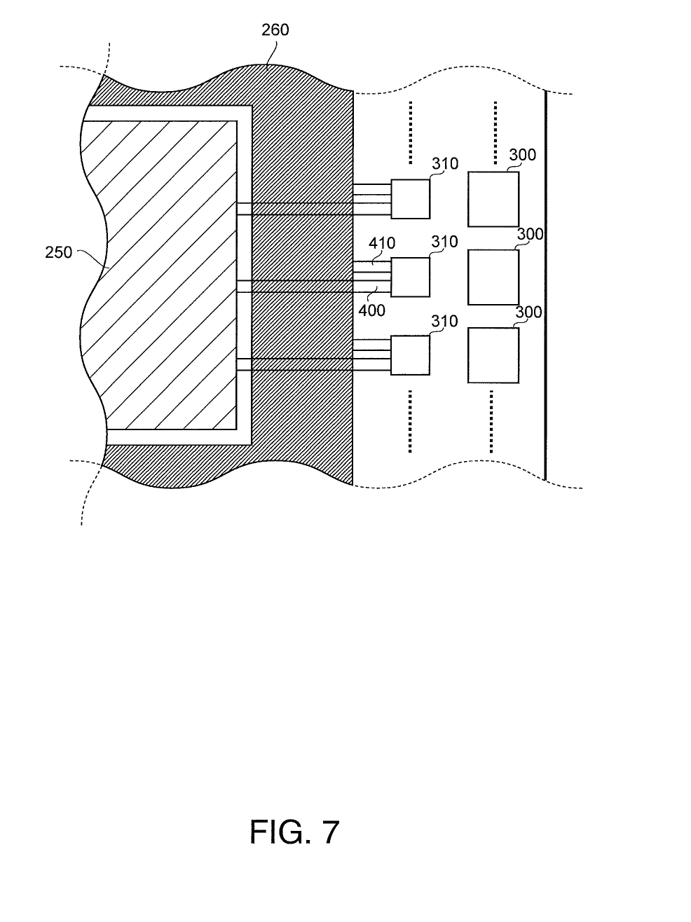

As the VCT electrode 260 is arranged so as to surround the VEL electrode 250, it is preferable that the other ends of the protection elements 312 constituting the protection circuits 310 be connected to the VCT electrode 260 by connection interconnects 410 forming the shortest paths, as shown in FIG. 7. Furthermore, as shown in FIG. 7, it is preferable that the electrooptical device 100 include connection interconnects 400 that connect the VEL electrode 250 and the other ends of the protection elements 314 constituting the protection circuits 310, and that the connection interconnects 400 be arranged so as to be superimposed with the VCT electrode 260 in a plan view. In this way, the shortest-path connection can be established not only between the other ends of the protection elements 312 and the VCT electrode 260, but also between the other ends of the protection elements 314 and the VEL electrode 250.

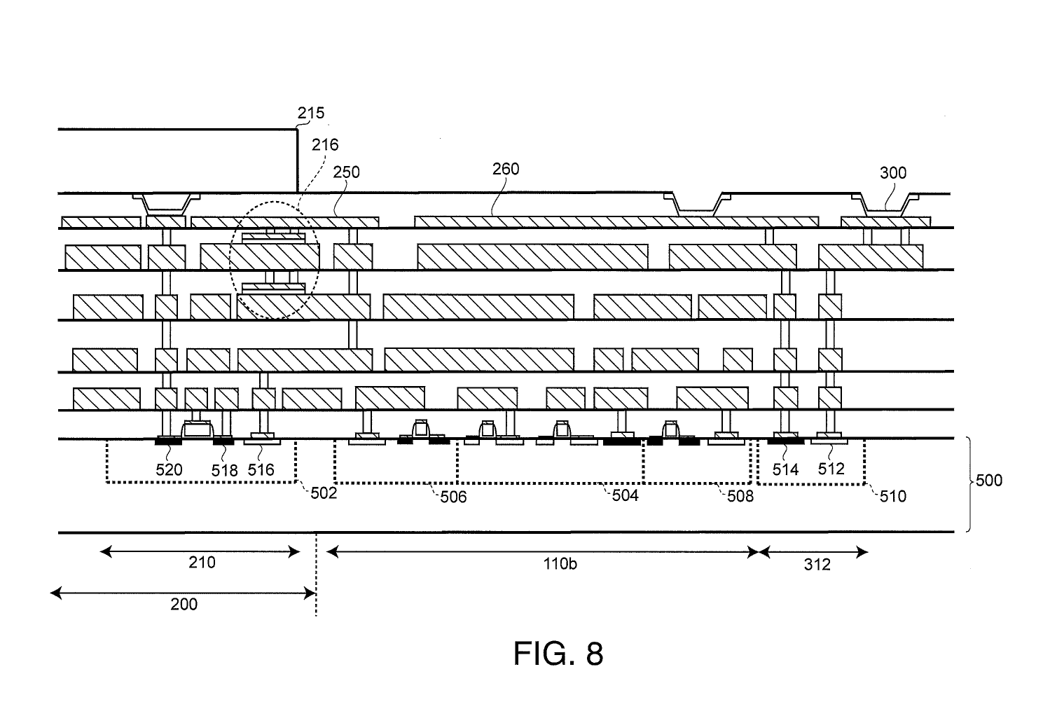

FIG. 8 schematically shows one example of a cross-sectional configuration of the electrooptical device 100 taken along line A-A of FIG. 2. Components of FIG. 8 that are similar to those of FIGS. 1 to 3 are given the same reference signs thereas, and a description thereof will be omitted as appropriate. While FIG. 8 shows one example of the cross-sectional configuration taken along line A-A that passes through the scan line drive circuit 110b, a cross-sectional configuration taken along a line that passes through the scan line drive circuit 110a is similar. Also note that the details of a cross-sectional configuration of the OLEDs 215 are omitted from FIG. 8.

The electrooptical device 100 is formed on a p-type semiconductor substrate 500. N-type impurity regions (wells) 502 and 504 and p-type impurity regions 506, 508 and 510 are formed on the p-type semiconductor substrate 500. A pixel circuit 210 is formed on the n-type impurity region 502. A part of circuits constituting the scan line drive circuit 110b is formed on the n-type impurity region 504 and the p-type impurity regions 506 and 508. The protection element 312 constituting the protection circuit 310 shown in FIG. 6 is formed on the p-type impurity region 510.

A pad 300 formed in a layer above the p-type semiconductor substrate 500 is connected to an n-type high concentration impurity region 512 formed in the p-type impurity region 510 via a plurality of wiring layers that are electrically connected via through-holes. A p-type high concentration impurity region 514 is further formed in the p-type impurity region 510. The p-type high concentration impurity region 514 is electrically connected to the VCT electrode 260 via the plurality of wiring layers that are electrically connected via the through-holes. The n-type high concentration impurity region 512 and the p-type high concentration impurity region 514 serve as a cathode and an anode of the protection diode, respectively. The n-type high concentration impurity region 512 and the p-type high concentration impurity region 514 together form the protection element 312. Although not shown in FIG. 8, a protection element 314 is formed in a similar manner.

The VCT electrode 260 is formed in a layer above transistors constituting the scan line drive circuit 110b.

A holding capacitor 216 is formed in a layer below the VEL electrode 250. In the holding capacitor 216, capacitances formed by conductive layers holding an insulating film therebetween are stacked. One end of the holding capacitor 216 is electrically connected to the VEL electrode 250 in the layer thereabove, and the other end thereof is connected to, for example, a gate of a non-illustrated transistor.

The VEL electrode 250 is electrically connected to an n-type high concentration impurity region 516 formed in the n-type impurity region 502 via the plurality of wiring layers that are electrically connected via the through holes. In the n-type impurity region 502, p-type active regions 518 and 520 are formed with a channel region therebetween. In a layer above the channel region, a gate electrode is formed via a gate oxide. The p-type active regions 518 and 520 serve as a source and a drain of a p-type transistor, respectively. The p-type active region 520 is electrically connected to an OLED 215 formed in a layer above the VEL electrode 250 via the plurality of wiring layers that are electrically connected via the through-holes.

In the present embodiment, protection elements constituting the protection circuits 330 that are located in the vicinity of the mount pads 320 are not connected to the VEL electrode 250 or the VCT electrode 260. This is because the protection elements can be connected to a power supply line that is connected to one of the mount pads 320 to which the voltage Vel or the voltage Vct is supplied by the minimum distance, compared to the case where they are connected to the VEL electrode 250 or the VCT electrode 260. However, the protection elements constituting the protection circuits 330 that are located in the vicinity of the mount pads 320 may also be connected to the VEL electrode 250 or the VCT electrode 260, similarly to the pads 300.

That is to say, while the pads according to the invention are arranged along each of at least three sides out of the outer peripheral sides of the substrate on which the electrooptical device 100 is formed, they may be one of the plurality of pads 300 arranged along the outer peripheral sides of the substrate, or the mount pads 320 in the electrooptical device 100.

As described above, in the present embodiment, the VEL electrode 250 or the VCT electrode 260, which is mutually connected to the plurality of OLEDs formed in the display unit 200, is connected to the protection elements constituting the protection circuits 310. In this way, even if the substrate on which the electrooptical device 100 is formed increases in size, static electricity that has entered from the pads can be efficiently discharged to lower-impedance electrodes compared to related art, without having to excessively arrange interconnects.

### Modification Examples

While the VCT electrode 260 is arranged so as to surround the VEL electrode 250 in FIG. 4, the VCT electrode 260 according to the present embodiment is not limited to having such a shape in a plan view. The VCT electrode may be configured as a plurality of electrodes that are arranged so as to surround the VEL electrode, or may be arranged such that it has outer peripheral sides extending along at least two sides out of the outer peripheral sides of the VEL electrode.

### 1. First Modification Example

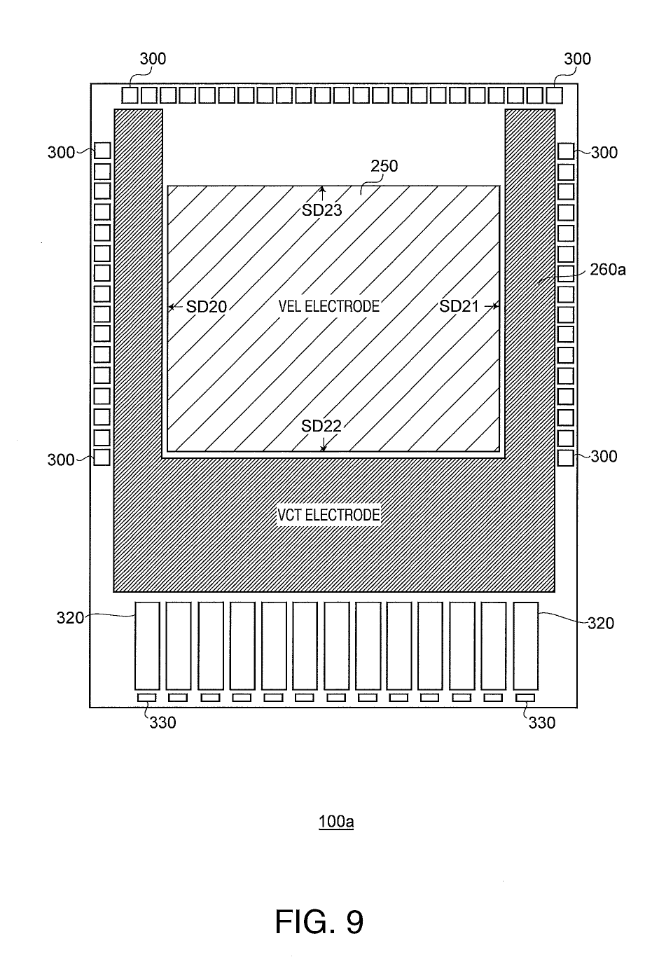

FIG. 9 shows one example of an arrangement of a VEL electrode and a VCT electrode in an electrooptical device according to a first modification example of the present embodiment in a plan view. Components of FIG. 9 that are similar to those of FIG. 4 are given the same reference signs thereas, and a description thereof will be omitted as appropriate.

The VEL electrode and the VCT electrode arranged in an electrooptical device 100a according to the first modification example differ from the VEL electrode 250 and the VCT electrode 260 arranged in the electrooptical device 100 of FIG. 4 in the shape of the VCT electrode in a plan view. In the electrooptical device 100a, a VCT electrode 260a has outer peripheral sides extending along three sides out of outer peripheral sides of a rectangular VEL electrode 250. In other words, the VCT electrode 260a has a squared-C shape or a U shape.

More specifically, the VCT electrode 260a has outer peripheral sides extending along sides SD20, SD21 and SD22 out of the outer peripheral sides of the VEL electrode 250. The sides SD20 and SD21 oppose each other, and the side SD22 intersects the sides SD20 and SD21. In FIG. 9, the side SD22 extends along a direction in which the mount pads 320 are arrayed. The VCT electrode 260a is electrically connected to any of the plurality of mount pads 320, and the voltage Vct is supplied to the VCT electrode 260a via the connected mount pad 320.

While an open side of the VCT electrode 260a is situated at a side SD23 opposing the side SD22 in FIG. 9, the open side may instead be situated at any of the sides SD20, SD21 and SD22.

According to the first modification example, interconnects connecting the pads 300 and the VCT electrode 260a can be further reduced in length, and the impedance of the VCT electrode 260a can be further lowered. Therefore, the first modification example allows for reduction in unevenness in display similarly to the present embodiment.

### 2. Second Modification Example

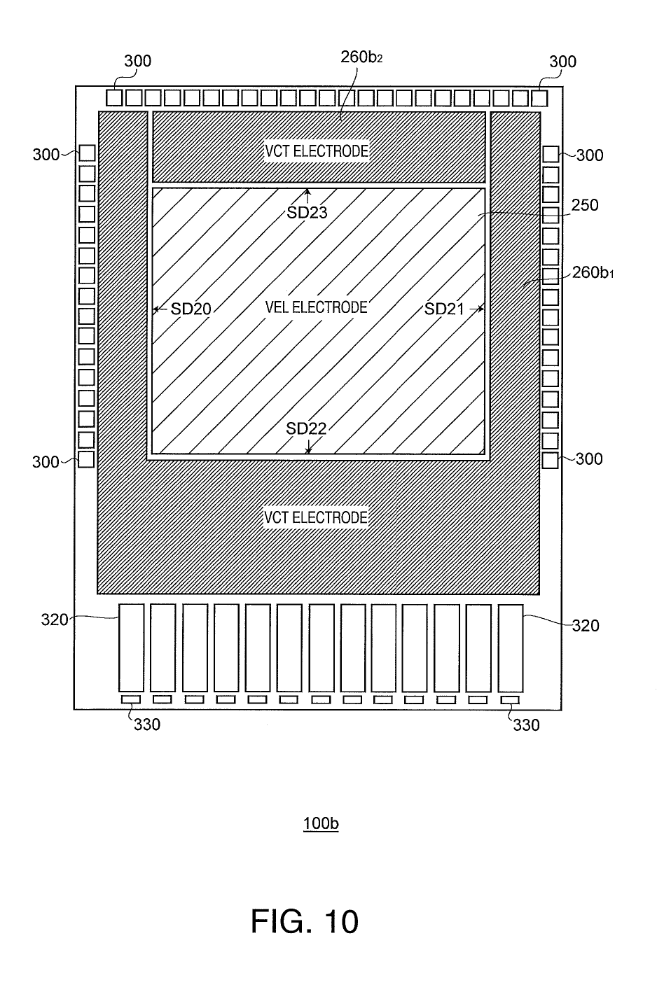

FIG. 10 shows one example of an arrangement of a VEL electrode and a VCT electrode in an electrooptical device according to a second modification example of the present embodiment in a plan view. Components of FIG. 10 that are similar to those of FIG. 4 or 9 are given the same reference signs thereas, and a description thereof will be omitted as appropriate.

The VEL electrode and the VCT electrode arranged in an electrooptical device 100b according to the second modification example differ from the VEL electrode 250 and the VCT electrode 260 arranged in the electrooptical device 100 of FIG. 4 in that the VCT electrode is arranged in a divided state. VCT electrodes 260b₁ and 260b₂ are formed in the electrooptical device 100b. Similarly to the VCT electrode 260a of FIG. 9, the VCT electrode 260b₁ has outer peripheral sides extending along three sides out of outer peripheral sides of a rectangular VEL electrode 250 of FIG. 10. In other words, the VCT electrode 260b₁ has a squared-C shape or a U shape. The VCT electrode 260b₂ has an outer peripheral side extending along the remaining one side out of the outer peripheral sides of the VEL electrode 250.

More specifically, the VCT electrode 260b₁ has outer peripheral sides extending along sides SD20, SD21 and SD22 out of the outer peripheral sides of the VEL electrode 250. The sides SD20 and SD21 oppose each other, and the side SD22 intersects the sides SD20 and SD21. The VCT electrode 260b₂ has an outer peripheral side extending along a side SD23 opposing the side SD22 out of the outer peripheral sides of the VEL electrode 250. That is to say, the VCT electrode 260b₂ is situated at an open side of the VCT electrode 260b₁. The VCT electrodes 260b₁ and 260b₂ are arranged so as to oppose each other, and hence surround the VEL electrode 250. The VCT electrodes 260b₁ and 260b₂ are electrically connected to any of the plurality of mount pads 320, and the voltage Vct is supplied to the VCT electrodes 260b₁ and 260b₂ via the connected mount pad 320.

While the open side of the VCT electrode 260b₁ is situated at the side SD23 in FIG. 10, the open side may instead be situated at any of the sides SD20, SD21 and SD22.

According to the second modification example, interconnects connecting the pads 300 and the VCT electrode 260b₁ or 260b₂ can be further reduced in length, and the impedances of the VCT electrodes 260b₁ and 260b₂ can be further lowered. Therefore, the second modification example allows for reduction in unevenness in display similarly to the present embodiment.

### 3. Third Modification Example

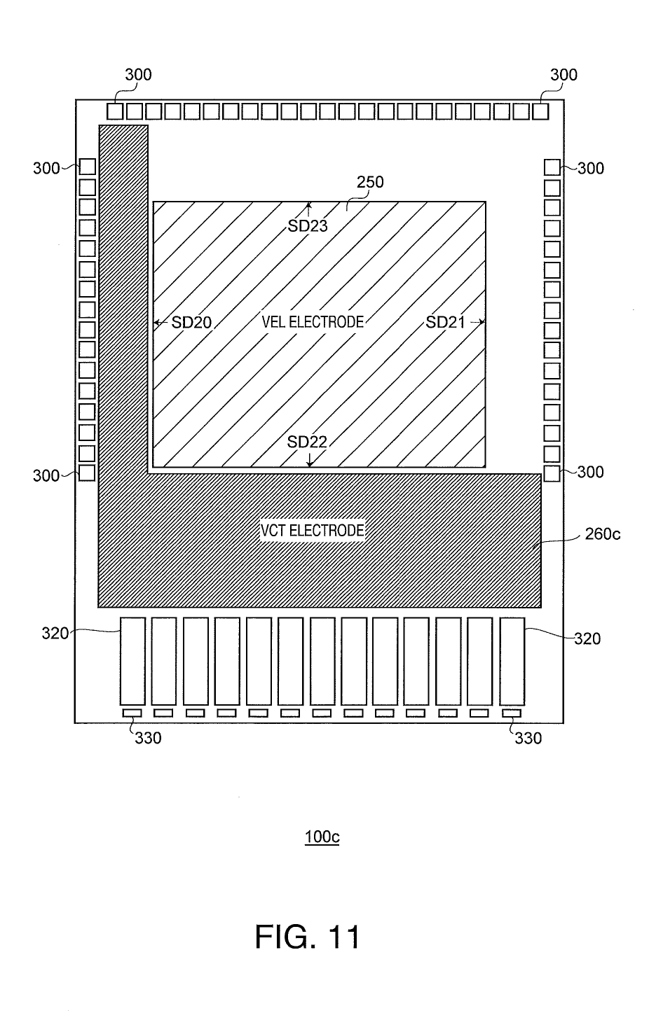

FIG. 11 shows one example of an arrangement of a VEL electrode and a VCT electrode in an electrooptical device according to a third modification example of the present embodiment in a plan view. Components of FIG. 11 that are similar to those of FIG. 4 or 9 are given the same reference signs thereas, and a description thereof will be omitted as appropriate.

The VEL electrode and the VCT electrode arranged in an electrooptical device 100c according to the third modification example differ from the VEL electrode 250 and the VCT electrode 260 arranged in the electrooptical device 100 of FIG. 4 in the shape of the VCT electrode in a plan view. In the electrooptical device 100c, a VCT electrode 260c has outer peripheral sides extending along two mutually-intersecting sides out of outer peripheral sides of a rectangular VEL electrode 250. In other words, the VCT electrode 260c has an L shape.

More specifically, the VCT electrode 260c has outer peripheral sides extending along mutually-intersecting sides SD20 and SD22 out of the outer peripheral sides of the VEL electrode 250. The VCT electrode 260c is electrically connected to any of the plurality of mount pads 320, and the voltage Vct is supplied to the VCT electrode 260c via the connected mount pad 320.

While the VCT electrode 260c has outer peripheral sides extending along the sides SD20 and SD22 in FIG. 11, the VCT electrode 260c may instead have outer peripheral sides extending along the sides SD20 and SD23, along the sides SD23 and SD21, or along the sides SD21 and SD22.

According to the third modification example, interconnects connecting the pads 300 and the VCT electrode 260c can be further reduced in length, and the impedance of the VCT electrode 260c can be further lowered. Therefore, the third modification example allows for reduction in unevenness in display similarly to the present embodiment.

### 4. Fourth Modification Example

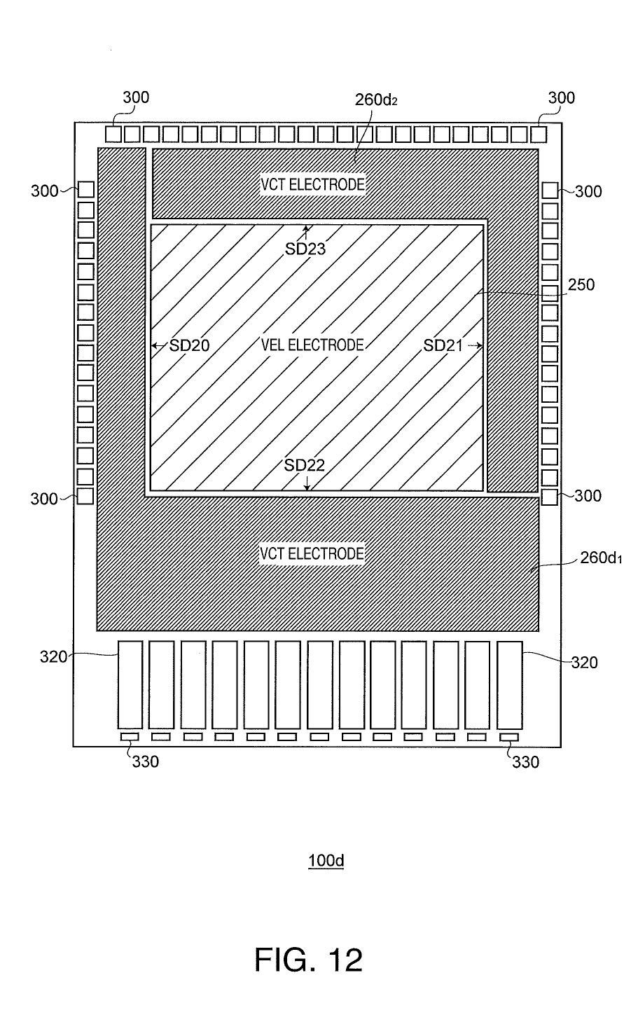

FIG. 12 shows one example of an arrangement of a VEL electrode and a VCT electrode in an electrooptical device according to a fourth modification example of the present embodiment in a plan view. Components of FIG. 12 that are similar to those of FIG. 4 or 9 are given the same reference signs thereas, and a description thereof will be omitted as appropriate.

The VEL electrode and the VCT electrode arranged in an electrooptical device 100d according to the fourth modification example differ from the VEL electrode 250 and the VCT electrode 260 arranged in the electrooptical device 100 of FIG. 4 in that the VCT electrode is arranged in a divided state. VCT electrodes 260d₁ and 260d₂ are formed in the electrooptical device 100d. Similarly to the VCT electrode 260c of FIG. 11, the VCT electrode 260d₁ has outer peripheral sides extending along two mutually-intersecting sides out of outer peripheral sides of a rectangular VEL electrode 250. In other words, the VCT electrode 260d₁ has an L shape. The VCT electrode 260d₂ similarly has outer peripheral sides extending along the remaining two mutually-intersecting sides out of the outer peripheral sides of the VEL electrode 250. In other words, the VCT electrode 260d₂ similarly has an L shape.

More specifically, the VCT electrode 260d₁ has outer peripheral sides extending along mutually-intersecting sides SD20 and SD22 out of the outer peripheral sides of the VEL electrode 250. The VCT electrode 260d₂ has outer peripheral sides extending along mutually-intersecting sides SD23 and SD21 out of the outer peripheral sides of the VEL electrode 250. That is to say, the VCT electrodes 260d₁ and 260d₂ are arranged so as to oppose each other, and hence surround the VEL electrode 250. The VCT electrodes 260d₁ and 260d₂ are electrically connected to any of the plurality of mount pads 320, and the voltage Vct is supplied to the VCT electrodes 260d₁ and 260d₂ via the connected mount pad 320.

While the VCT electrode 260d₁ has outer peripheral sides extending along the sides SD20 and SD22 and the VCT electrode 260d₂ has outer peripheral sides extending along the sides SD23 and SD21 in FIG. 12, the VCT electrode 260d₁ may instead have outer peripheral sides extending along the sides SD20 and SD23, and the VCT electrode 260d₂ may instead have outer peripheral sides extending along the sides SD21 and SD22.

According to the fourth modification example, interconnects connecting the pads 300 and the VCT electrode 260d₁ or 260d₂ can be further reduced in length, and the impedances of the VCT electrodes 260d₁ and 260d₂ can be further lowered. Therefore, the fourth modification example allows for reduction in unevenness in display similarly to the present embodiment.

Electronic Apparatus

By configuring a display module using the electrooptical device 100 according to the present embodiment and a flexible printed circuit (hereinafter referred to as FPC) board, the electrooptical device 100 can be installed in an electronic apparatus in a more simplified manner.

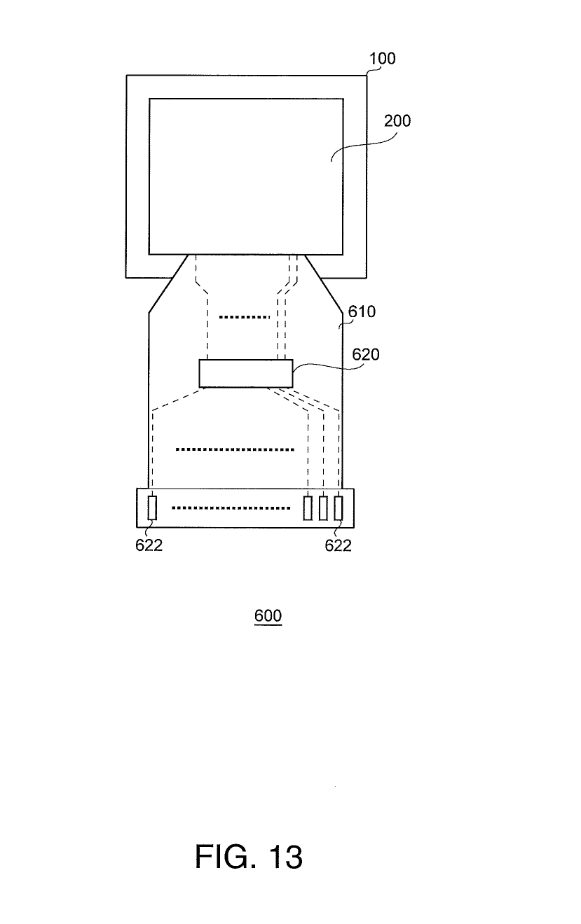

FIG. 13 shows one example of a configuration of a display module to which the electrooptical device 100 according to the present embodiment is applied.

A display module 600 includes the electrooptical device 100 and an FPC board 610. The FPC board 610 includes a plurality of mount terminals (not shown in the drawings) connected to the mount pads 320 of the electrooptical device 100, an integrated circuit device 620 mounted using a COF (chip-on-film) technique, and a plurality of terminals 622 connected to an external circuit. In the FPC board 610 are formed wires electrically connecting the plurality of mount terminals and terminals of the integrated circuit device 620, and wires electrically connecting terminals of the integrated circuit device 620 and the plurality of terminals 622.

The integrated circuit device 620 has functions of the control circuit 150 and the power supply circuit 160 of FIG. 1, and controls display of the electrooptical device 100.

The electrooptical device 100 according to the present embodiment, or the display module 600 using the same, can be applied to the following electronic apparatus.

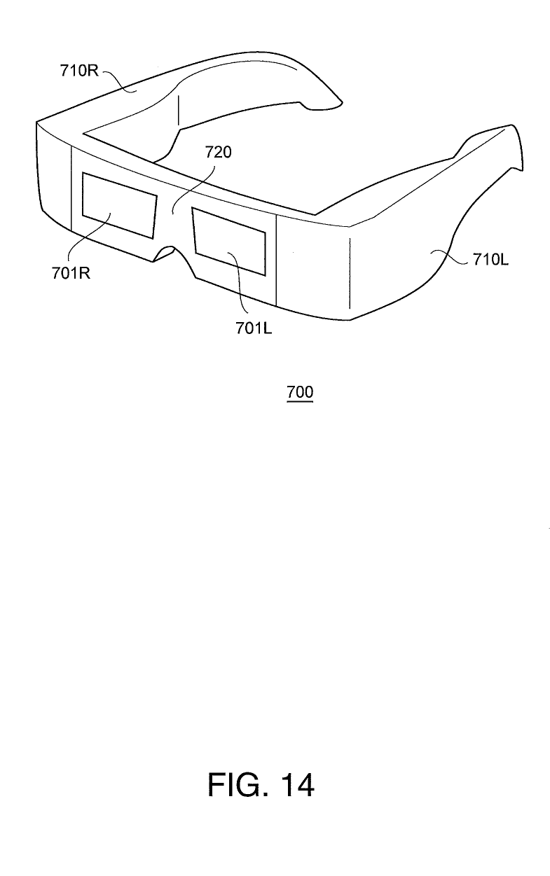

FIG. 14 shows an external appearance of an HMD serving as an electronic apparatus according to the present embodiment.

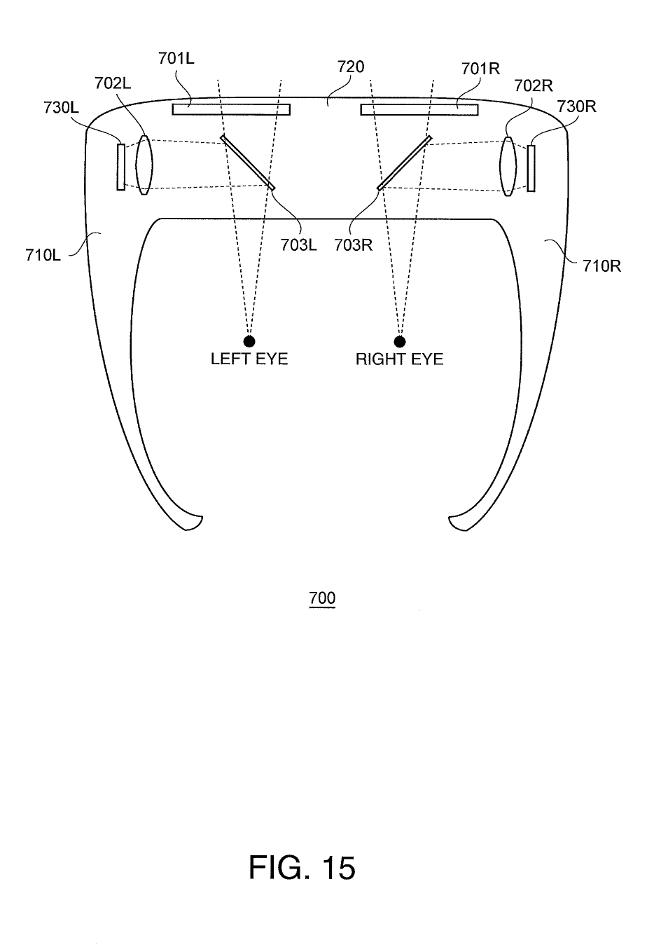

FIG. 15 shows an overview of an optical configuration of the HMD shown in FIG. 14. Components of FIG. 15 that are similar to those of FIG. 14 are given the same reference signs thereas, and a description thereof will be omitted as appropriate.

An HMD 700 according to the present embodiment includes temples 710L and 710R, a bridge 720, and lenses 701L and 701R. As shown in FIG. 15, the HMD 700 includes an electrooptical device 730L (or a display module equipped with the electrooptical device 730L) and an optical lens 702L for the left eye in the vicinity of the temple 710L and the lens 701L. Also, as shown in FIG. 15, the HMD 700 further includes an electrooptical device 730R (or a display module equipped with the electrooptical device 730R) and an optical lens 702R for the right eye in the vicinity of the temple 710R and the lens 701R.

Also, as shown in FIG. 15, the HMD 700 further includes half-silvered mirrors 703L and 703R that are respectively arranged on optical paths along which light from the lenses 701L and 701R is incident on the left and right eyes. The electrooptical device 100 according to the present embodiment can be used as each of the electrooptical devices 730L and 730R.

An image display surface of the electrooptical device 730L is arranged to face the right side of FIG. 15. The half-silvered mirror 703L is irradiated with light corresponding to an image displayed by the electrooptical device 730L via the optical lens 702L. The half-silvered mirror 703L reflects light from the optical lens 702L toward the position of the left eye, and allows light from the lens 701L to be transmitted toward the position of the left eye.

An image display surface of the electrooptical device 730R is arranged to face the left side of FIG. 15. The half-silvered mirror 703R is irradiated with light corresponding to an image displayed by the electrooptical device 730R via the optical lens 702R. The half-silvered mirror 703R reflects light from the optical lens 702R toward the position of the right eye, and allows light from the lens 701R to be transmitted toward the position of the right eye.

In this way, images displayed by the electrooptical devices 730L and 730R are perceived by a wearer of the HMD 700 as see-through images composited with the external view seen through the lenses 701L and 701R.

At this time, the wearer can recognize stereoscopic images by causing the electrooptical devices 730L and 730R in the HMD 700 to respectively display images for the left and right eyes out of binocular parallax images.

By applying the electrooptical device 100 according to the present embodiment to the HMD 700, measures against ESD damage can be sufficiently taken, and higher-quality images can be displayed.

While the electrooptical device, the electronic apparatus, and the like according to the invention have been described herein based on the embodiments, the invention is by no means limited to the embodiments. For example, the invention can be embodied in various aspects without departing from the concept thereof. Following modifications are also possible.

(1) In the present embodiment, the electrooptical device 100 has been described based on the configuration shown in FIG. 1 as an example. However, the invention is not limited in this way.

(2) In the present embodiment, circuits and electrodes in the electrooptical device 100 have been described to conform to the arrangements shown in FIGS. 2 and 4. However, the invention is not limited in this way.

(3) In the present embodiment, the pixel circuits 210 have been described based on the configuration shown in FIG. 3 as an example. However, the invention is not limited in this way.

(4) In the present embodiment, transistors constituting the pixel circuits 210 have been described as p-type MOS transistors. However, the invention is not limited in this way. At least one of the transistors constituting each pixel circuit 210 may be an n-type MOS transistor.

(5) In the present embodiment, an HMD has been described as an example of an electronic apparatus to which the electrooptical device 100 is applied. However, the invention is not limited in this way. For example, the electronic apparatus according to the invention may be an apparatus using a direct-view display panel, such as an EVF, as a microdisplay.

Other examples of the electronic apparatus according to the invention include: a PDA (personal digital assistant), a digital still camera, a television, a video camera, a car navigation device, a pager, an electronic organizer, an electronic paper, a calculator, a word processor, a workstation, a videophone, a POS (point of sale system) terminal, a printer, a scanner, a copier, a video player, and an apparatus equipped with a touchscreen.

(6) In the present embodiment, the invention has been described as the electrooptical device, the electronic apparatus, and the like. However, the invention is not limited in this way. For example, the invention may be a method for protecting elements in the electrooptical device according to the invention and the like.

What is claimed is:

1. An electrooptical device comprising:
a pad;
a plurality of organic light-emitting diodes;
a first electrode that is electrically and mutually connected to cathodes of the plurality of organic light-emitting diodes; and
a first protection element that is electrically connected to the pad at one end and to the first electrode at the other end.

2. The electrooptical device according to claim 1, wherein
the first protection element is one of a protection diode, an off transistor, and a thyristor.

3. The electrooptical device according to claim 1, further comprising:
a plurality of drive transistors that supply current to the plurality of organic light-emitting diodes;
a second electrode that is electrically and mutually connected to sources of the plurality of drive transistors; and
a second protection element that is electrically connected to the pad at one end and to the second electrode at the other end.

4. The electrooptical device according to claim 3, wherein
the second protection element is a protection diode or an off transistor.

5. The electrooptical device according to claim 3, wherein
the second electrode is arranged so as to be superimposed with a display area in which the plurality of organic light-emitting diodes are formed in a plan view, and
the first electrode is constituted by one or more electrodes that are arranged so as to surround the second electrode.

6. The electrooptical device according to claim 3, wherein
the second electrode is arranged so as to be superimposed with a display area in which the plurality of organic light-emitting diodes are formed in a plan view, and
the first electrode has outer peripheral sides extending along two mutually-intersecting sides out of outer peripheral sides of the second electrode.

7. The electrooptical device according to claim 3, further comprising
a connection interconnect that electrically connects the second electrode and the other end of the second protection element, wherein
the connection interconnect is arranged so as to be superimposed with the first electrode in a plan view.

8. The electrooptical device according to claim 1, further comprising
a power supply pad to which a ground voltage is supplied, wherein
a synthetic impedance combining an impedance of an interconnect connecting the first electrode and the first protection element and an impedance of the first electrode is lower than an impedance of an interconnect electrically connected to the power supply pad.

9. The electrooptical device according to claim 1, wherein
the pad is one of a plurality of pads that are arranged along outer peripheral sides of a substrate on which the electrooptical device is formed.

10. The electrooptical device according to claim 1, wherein
the pad is arranged along each of at least three sides out of outer peripheral sides of a substrate on which the electrooptical device is formed.

11. The electrooptical device according to claim 1, wherein
the pad is a mount pad for the electrooptical device.

12. An electronic apparatus comprising the electrooptical device according to claim 1.
